(19) United States
(12) Patent Application Publication
(10) Pub. No.: US 2025/0227921 A1
(43) Pub. Date: Jul. 10, 2025

(54) SEMICONDUCTOR DEVICE AND METHOD OF MANUFACTURING THE SAME

(71) Applicant: Fujian Jinhua Integrated Circuit Co., Ltd., Quanzhou City (CN)

(72) Inventors: Li-Wei Feng, Quanzhou City (CN); Yirong Xu, Quanzhou City (CN); Janbo Zhang, Quanzhou City (CN)

(73) Assignee: Fujian Jinhua Integrated Circuit Co., Ltd., Quanzhou City (CN)

(21) Appl. No.: 18/628,825

(22) Filed: Apr. 8, 2024

(30) Foreign Application Priority Data
Jan. 8, 2024 (CN) 202410026811.2

(51) Int. Cl. H10B 12/00

(52) U.S. Cl. CPC H10B 12/50; H10B 12/09; H10B 12/315; H10B 12/482

(57) ABSTRACT

The invention discloses a semiconductor structure, comprising: a substrate comprising a first region and a second region, a gate structure disposed on the substrate structure of the second region, a sidewall structure disposed on two sides and top surface of the gate structure, a first dielectric layer disposed on the sidewall structure, a second dielectric layer disposed on the first dielectric layer, a first insulating structure disposed in the second dielectric layer, and a second insulating structure penetrating through the first insulating structure.

### BACKGROUND OF THE INVENTION

### 1. Field of the Invention

The present invention relates to a semiconductor device and method of manufacturing the same, more particularly, to a semiconductor device comprising a contact isolation structure and a contact pad isolation structure and method of manufacturing the same.

### 2. Description of the Prior Art

Because of the features such as small size, multifunctionality, and/or low manufacturing cost etc., semiconductor devices have been widely used in the electronics industry. Semiconductor devices can be classified into semiconductor memory devices for storing logical data, semiconductor logic devices for processing operations of logical data, and hybrid devices for functions of both memory devices and logic devices.

Some semiconductor devices can comprise vertically stacked layer structure pattern and contact plugs or interconnect structures that electrically connect stacked patterns to each other. As semiconductor devices continually become smaller and increase integration density, such spacing between patterns and/or the spacing between patterns and contact plugs is also continuously reduced. Therefore, the parasitic capacitance between the patterns and/or between the pattern and the contact plug increases, and the contact resistance between the patterns and the interconnected structures increase as well, leading to performance degradation in the semiconductor device, such as decreased operating speed.

### SUMMARY OF THE INVENTION

In light of the abovementioned conventional problems encountered by semiconductor devices, the present invention hereby provides a novel semiconductor device and method of manufacturing the same, wherein a special isolation structure is between a storage node contact and a storage node contact pad, which may reduce the k value of the overall device and its parasitic capacitance.

One aspect of the present invention is to provide a semiconductor device, comprising a substrate comprising a first region and a second region, a gate structure disposed on said substrate of said second region, a sidewall structure disposed on two sides and top surface of said gate structure, a first dielectric layer disposed on said sidewall structure, a second dielectric layer disposed on said first dielectric layer, a first insulating structure disposed in said second dielectric layer, and a second insulating structure penetrating through said first insulating structure.

Another aspect of the present invention is to provide a method of manufacturing semiconductor structure, comprising providing a substrate comprising a first region and a second region, forming a gate structure on said substrate of said second region, forming a sidewall structure on two sides and top surface of said gate structure, forming a first dielectric layer on said sidewall structure, forming a second dielectric layer on said first dielectric layer, forming a first insulating structure in said second dielectric layer, and forming a second insulating structure penetrating through said first insulating structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are comprised to provide a further understanding of the embodiments, and are incorporated in and constitute a part of this specification. The drawings illustrate some of the embodiments and, together with the description, serve to explain their principle.

In the drawings:

FIG. 1A, FIG. 2A, FIG. 3A, FIG. 4A, FIG. 5A, FIG. 6A and FIG. 7A are schematic plan views illustrating a process flow of a semiconductor device in accordance with one embodiment of present invention;

FIG. 1B, FIG. 2B, FIG. 3B, FIG. 4B, FIG. 5B, FIG. 6B and FIG. 7B are schematic cross-sections illustrating a process flow of a semiconductor device in accordance with one embodiment of present invention;

FIG. 2C is a schematic cross-section illustrating a process flow of a semiconductor device in accordance with another embodiment of present invention;

FIGS. 8-11 are schematic cross-sections illustrating a process flow of a semiconductor device in accordance with another embodiment of present invention; and

FIG. 12 is a schematic cross-section illustrating a semiconductor device in accordance with another embodiment of present invention;

### DETAILED DESCRIPTION

Reference will now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

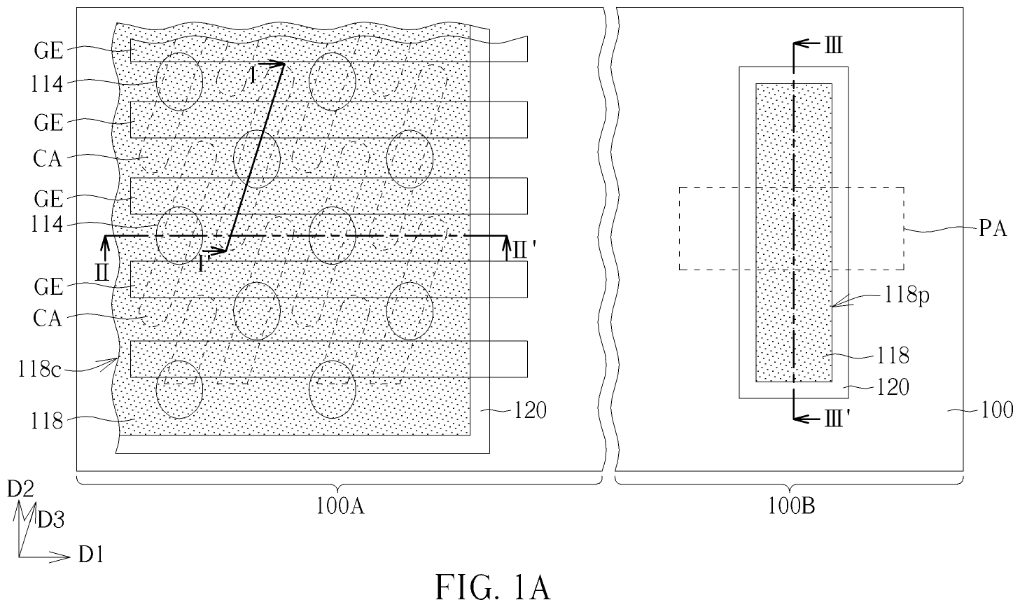

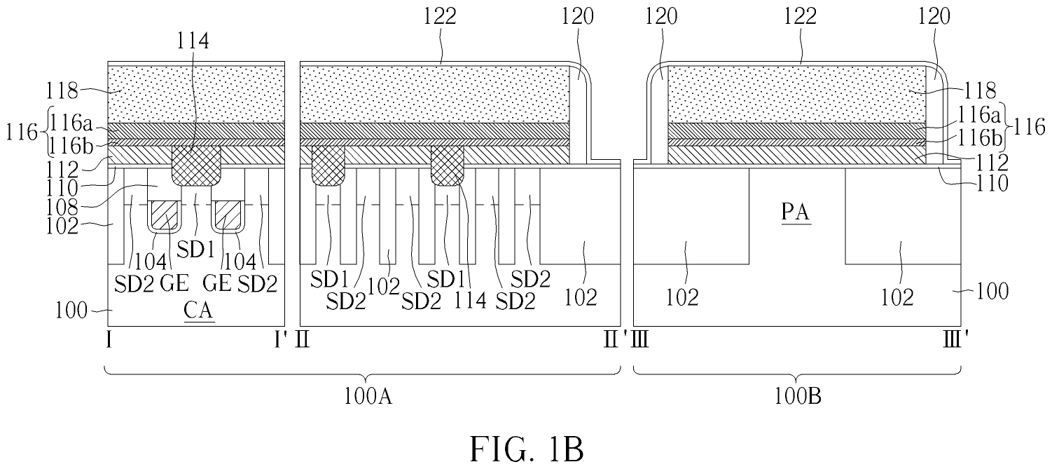

Hereinafter the invention will be described in detail with reference to the accompanying drawings, which form a part hereof and show by way of drawings and specific embodiments in which the invention may be carried out. These embodiments are described in sufficient detail to enable those of ordinary skill in the art to practice the invention. For the sake of simplicity and convenience, the scale and proportion of some parts in the illustrations may be deliberately reduced or expressed in an exaggerated manner. Without departing from the scope of the present disclosure, the invention may also adopt other embodiments or have structural, logical and electrical changes in which FIGS. 1A-7A depict plan views of a method for manufacturing semiconductor devices according to some embodiments, and FIGS. 1B-7B are cross-section taken along lines I-I′, Π-Π′, and III-III′ of FIGS. 1A to 7A, respectively.

Firstly, please refer to FIGS. 1A and 1B. At the beginning of the process, a semiconductor substrate 100 is provided as a setting basis for the semiconductor structure of the present invention. The semiconductor substrate 100 may comprise an adjacent first region 100A (for example, storage region 100A) and a second region 100B (for example, peripheral region 100B). Multiple storage cells may be formed on storage region 100A, and the peripheral transistors constituting a peripheral circuit may be formed in peripheral region 100B. The semiconductor substrate 100 may be a silicon (Si) substrate, a germanium (Ge) substrate, or a silicon-germanium (SiGe) substrate. A device isolation pattern 102 may be formed on or in semiconductor substrate 100 to define the cell active portions CA in the storage region 100A and to define the peripheral active part PA in the peripheral region 100B. In one embodiment, each cell active portion CA may be arranged in form of islands in plain view, which may correspond to the part of the semiconductor substrate 100 surrounded by the device isolation pattern 102. The device isolation pattern 102 may be formed through the technology of shallow trench isolation (STI), which material may comprise oxides (such as silicon oxide), nitrides (such as silicon nitride) and/or nitrogen oxides (such as silicon oxynitride).

Refer still to FIGS. 1A and 1B. In one embodiment, the semiconductor substrate 100 contains a cell gate electrode GE (as word line), and each cell active part CA crosses a pair of cell gate electrode GE. The cell gate electrode GE is embedded in the groove 104 of the semiconductor substrate 100, which extends in a first direction D1 and crosses the cell active part CA of the storage region 100A, and top surface may be lower than the top surface of cell active part CA on two sides of the groove 104. A cell gate insulating layer 106 is also provided between the cell gate electrode GE and the semiconductor substrate 100, which electrically isolates the cell gate electrode GE and the semiconductor substrate 100. A cell gate capping pattern 108 on top of each cell gate electrode GE fills up the remaining groove 104 and is flush with cell active part CA.

In one embodiment, the cell gate capping pattern 108 is further used as mask in the cell active part CA to form the first and second source/drain regions SD1 and SD2. Each cell gate electrode GE and its adjacent first and second source/drain regions SD1 and SD2 may constitute a cell selection component. In other words, the cell selection component may be a field effect transistor.

Refer still to FIGS. 1A and 1B. In one embodiment, the insulating layer 110 may be formed on the cell active part CA and the peripheral active part PA. A conductive layer may be formed on substrate 100 with insulating layer 110, with its part on storage region 100A extending through the insulating layer 110, thereby respectively connected to the first source/drain region SD1. Specifically, in one embodiment, the conductive layer may comprise a lower conductive layer 112, a contact plug 114, and an upper conductive layer 116. The lower conductive layer 112 may be formed on entire surface of semiconductor substrate 100 with insulating layer 110, and each contact plug 114 respectively connects to first source/drain region SD1.

The upper conductive layer 116 may be formed on the lower conductive layer 112 and the contact plug 114. In addition, the upper conductive layer 116 may further comprise a conductive barrier layer 116b disposed between the metal layer 116a and the lower conductive layer 112. The material of the conductive barrier layer 116b may be metal nitrides (such as titanium nitride, tantalum nitride and/or tungsten nitride) or transition metals (such as titanium or tantalum). In one embodiment, a hard mask layer 118 is formed on the upper conductive layer 116. The material of the hard mask layer 118 has etch selectivity with respect to the conductive layers (i.e., the upper conductive layer 116, the lower conductive layer 112, and the contact plug 114), such as silicon nitride and/or silicon oxynitride. As shown in FIG. 1A, the pattern of the stacked structure such as the lower conductive layer 112, the upper conductive layer 116, and the hard mask layer 118 are formed on the storage region 100A and the peripheral region 100B, and it can be seen that the peripheral gate pattern 118p of the peripheral transistor is formed in the peripheral region 100B, a plate pattern 118c is formed in the storage region 100A, and the cell gate electrode GE can extend beyond the plate pattern in the horizontal first direction D1 for subsequent connection to peripheral transistors.

Refer still to FIGS. 1A and 1B. After the plate pattern 118c and the peripheral gate pattern 118p are formed, spacers 120 are formed on the sidewall of the plate pattern 118c and the peripheral gate pattern 118p, and its material may be silicon oxide, silicon nitride and/or silicon oxynitride. The spacer 120 on peripheral region 100B may be used to define light doped drain (LDD) structure and extending structure of the source/drain region of peripheral region. In one embodiment, an insulating liner 122 may be conformally formed on the structural topography of the semiconductor substrate 100. The insulating liner 122 may be formed of the insulating material with etching selectivity with respect to the planarized interlayer dielectric 124 formed in a subsequent process. The insulating liner 122 in the peripheral region 100B is then be used as an etching stop layer in the process for forming the peripheral contact hole.

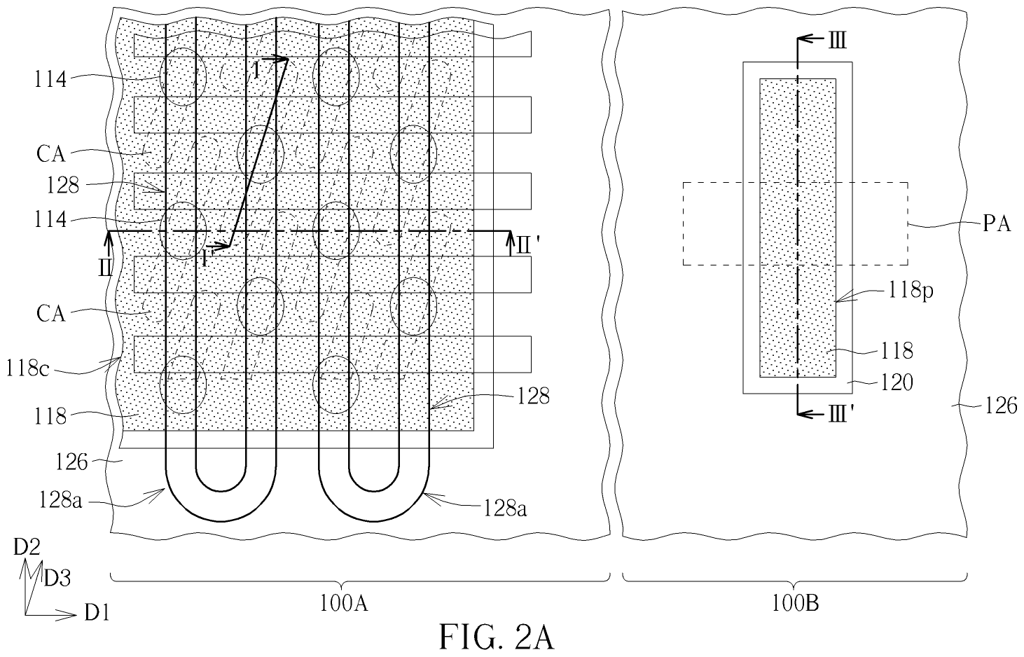

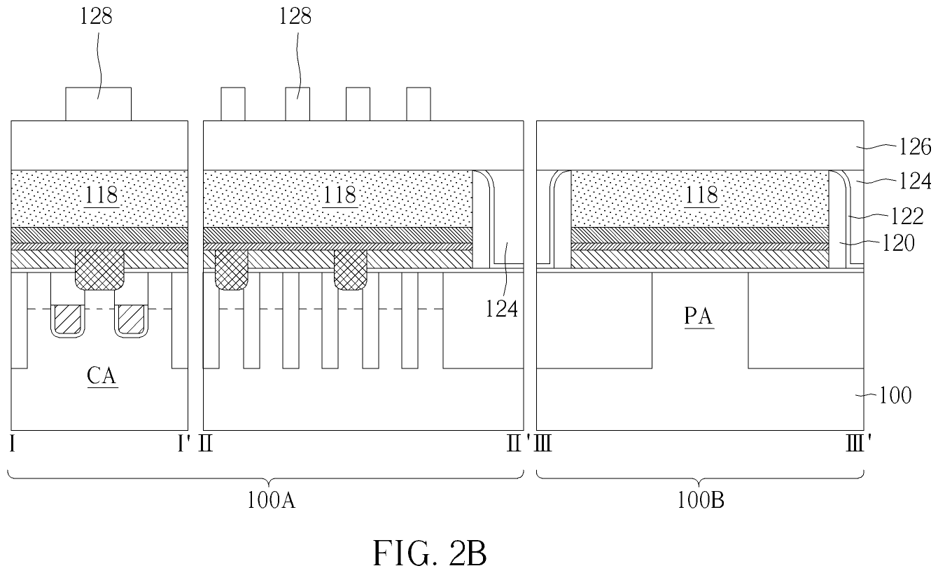

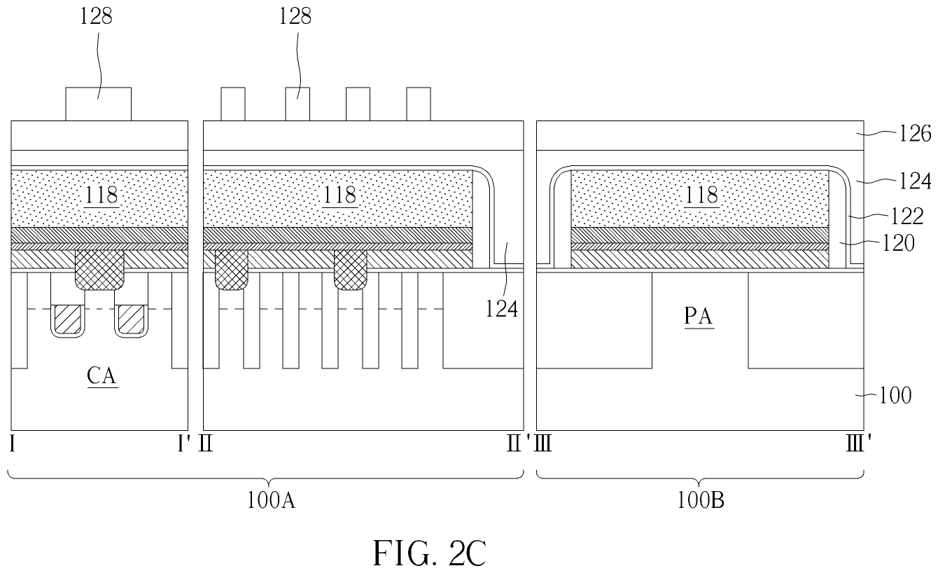

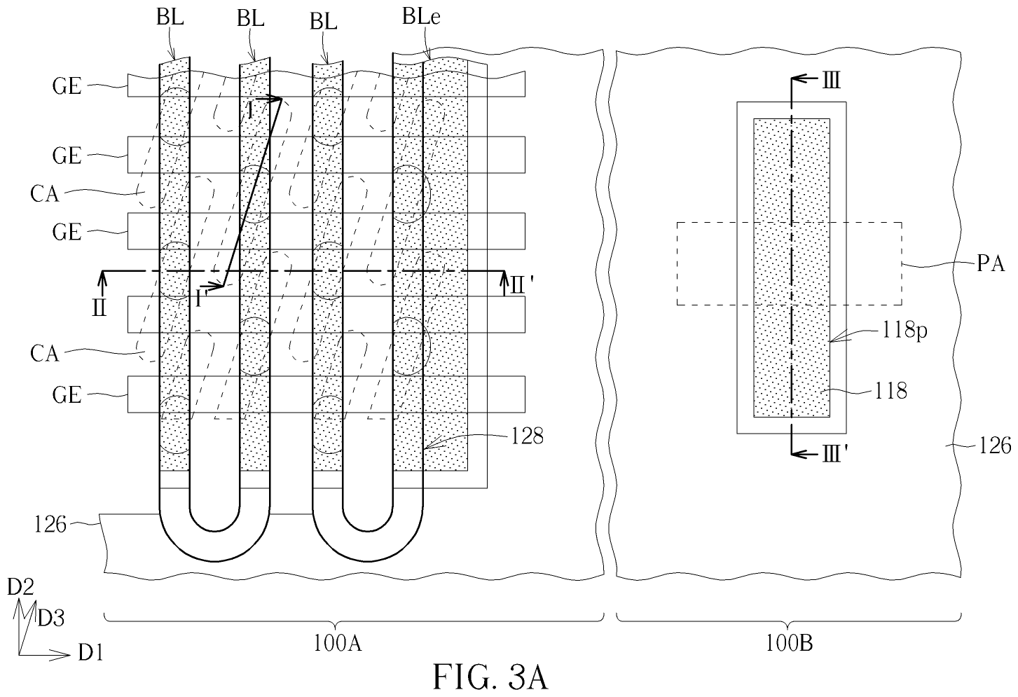

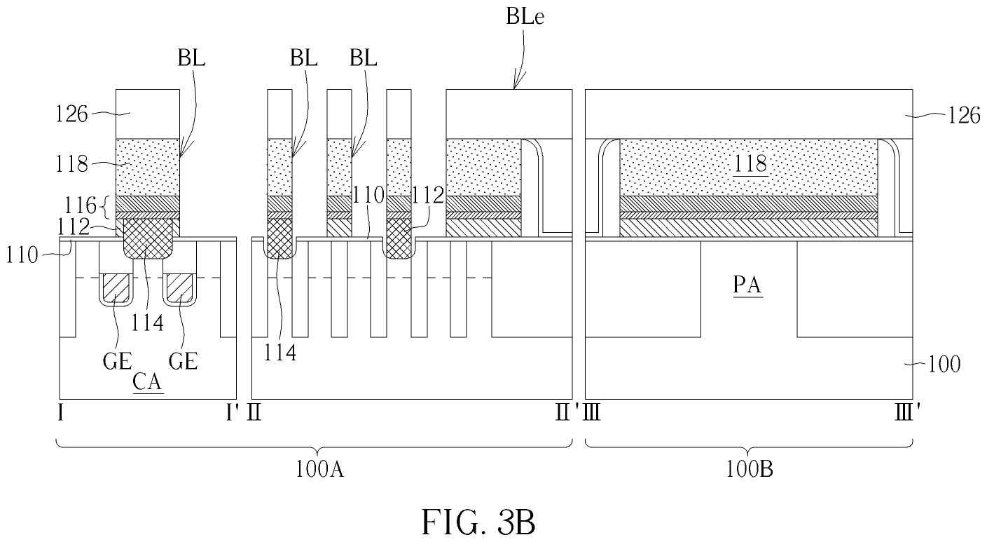

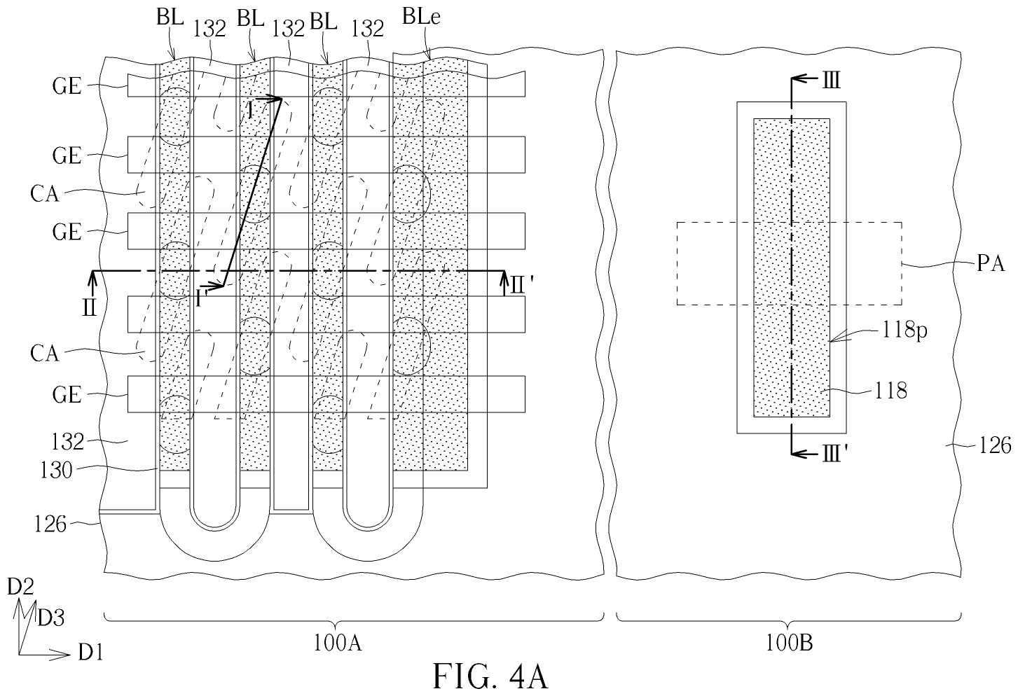

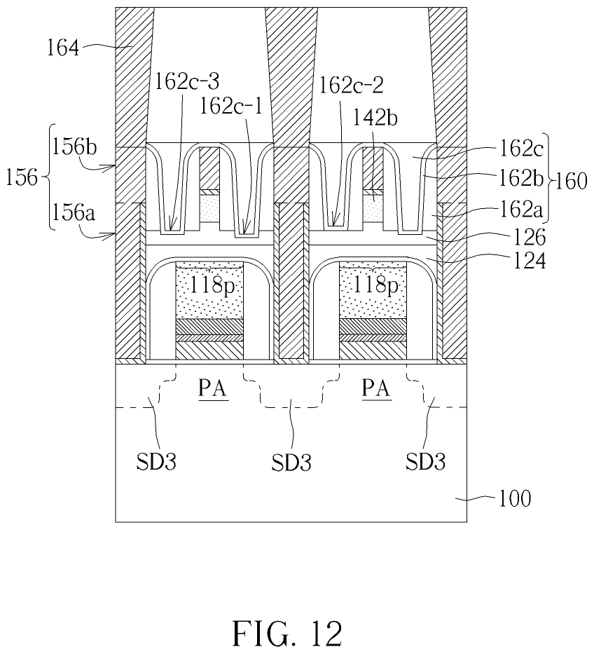

Please refer to FIGS. 2A and 2B. After the insulating liner 122 is formed, an interlayer dielectric (ILD) 124 is then formed on whole surface of the semiconductor substrate 100. In the embodiment, the planarized interlayer dielectric 124 is flush with the hard mask layer 118 on the storage region 100A and the peripheral region 100B, and the insulating liner 122 originally on the top surface of the hard mask layer 118 is removed to expose the hard mask layer 118. However, in other embodiment, as shown in FIG. 2C, the interlayer dielectric 124 may also cover the top surface of the hard mask layer 118 (as shown in FIG. 12), and the insulating liner 122 on the top surface of the hard mask layer 118 may not to be removed, but is not limited thereto. In one embodiment, the material of the interlayer dielectric 124 may be silicon oxide, and the material of the insulating liner 122 may be silicon nitride and/or silicon oxynitride. Then, a capping layer 126 is formed on the flush plane of the hard mask layer 118 and the interlayer dielectric 124. The capping layer 126 may be formed by an insulating material with etching selectivity with respect to the interlayer dielectric, such as silicon nitride and/or silicon oxynitride.

Refer still to FIGS. 2A and 2B. After the capping layer 126 is formed, the cell line mask pattern 128 is then formed on the capping layer 126. In one embodiment, the cell line mask pattern 128 on the storage region 100A may extend in parallel to each other in the second direction D2, thereby crossing the plate pattern 118c. The cell line mask pattern 128 may be formed by a double patterning technology, so that its width can be smaller than the limit of the photolithography tool. The cell line mask pattern 128 formed using the double patterning method has a connection part 128a in the second direction D2, which does not overlap with the plate pattern 118c. More specifically, as shown in FIG. 2A, the cell line mask pattern 128 may overlap with the contact plug 114 in the same row located in the middle of all cell active portions CA but does not overlap with the end of all cell active portions CA. The cell line mask pattern 128 is not formed on peripheral region 100B.

Please refer to FIGS. 3A and 3B. After the cell line mask pattern 128 is formed, a photolithography process is then performed using the cell line mask pattern 128 as a mask to pattern the plate pattern 118c on the storage region 100A. Meanwhile, the etching rate of the etching recipe may vary depending on the etching area, wherein the etching rate of the capping layer 126 with large region (such as the capping layer 126 outside cell line mask pattern 128 and on the peripheral region 100B) may be lower than etching rate of capping layer 126 with small region (such as the capping layer 126 between cell line mask patterns 128). Therefore, the capping layer 126 between cell line mask patterns 128 and the hard mask layer 118 of plate pattern 118c thereunder may be etched sequentially. Conversely, the capping layer 126 on peripheral region 100B may be preserved. In addition, the capping layer 126 with large region on storage region 100A may be preserved. In other embodiments, optionally, additional photoresist patterns may be formed on the edge of storage region 100A and peripheral region 100B to achieve the above effects. Afterward, etching is continually with the patterned hard mask layer 118 and stops at insulation layer 110, so as to form the bit line pattern BL and the outermost bit line pattern BLe as shown in FIG. 3A, wherein the width of the outermost bit line pattern BLe in the first direction D1 is larger than the bit line pattern BL, which can be used as a dummy bit line pattern to avoid defects caused by micro-loading effect on the bit line pattern. The cell line mask pattern 128 can be removed after the hard mask layer 118 is patterned.

Refer still to FIGS. 3A and 3B. The bit line pattern BL extends in second direction D2 and is orthogonal to the cell gate electrode GE (as word line) in which the lower conductive layer 112 and contact plug 114 may be alternately and repeatedly disposed in the second direction D2, and the contact plug 114 is connected to the corresponding first source/drain region SD1. The insulating layer 110 may be disposed between the lower conductive layer 112 and the semiconductor substrate 100. The bit line pattern BL further comprises a stacked structure on the lower conductive layer 112 and contact plug 114 such as an upper conductive layer 116, a hard mask layer 118, and a capping layer 126. As seeing, the plate pattern 118c on the storage region 100A is transformed into multiple bit line patterns BL during this process, and peripheral gate pattern 118p on peripheral region 100B remains the same.

Please refer to FIGS. 4A and 4B. After the bit line pattern BL is formed, a conformal cell insulating liner 130 is then formed on the entire surface topography of the semiconductor substrate 100, and the filling insulating layer 132 is formed on the cell insulating liner 130 and in the air gap between the bit line patterns BL, BLe. In one embodiment, the cell insulating liner 130 is conformally formed on the sidewalls of the stacked structure such as the capping layer 126, the hard mask layer 118, the upper conductive layer 116, the lower conductive layer 112, and the contact plug 114 on the storage region 100A and on the surface of the insulating layer 110, the filling insulation layer 132 may fill up the air gap between the bit line patterns BL, BLe and extend in parallel to each other in the second direction D2. The planarized filling insulating layer 132 may expose the capping layer 126, which is flush with the capping layer 126 and the top surface of the cell insulating liner 130, and the cell insulating liner 130 and the filling insulating layer 132 on the peripheral region 100B are removed. The cell insulating liner 130 may be formed of an insulating material with etching selectivity with respect to the filling insulating layer 132, such as silicon nitride and/or silicon oxynitride, which may serve as the insulating layer between the storage node contact and the insulation layer between the bit line patterns BL later. The filling insulating layer 132 may be formed of silicon oxide, which can define the storage node contact isolation structure together with the bit line pattern BL in subsequent processes. It is noted that, in other embodiments, the cell insulating liner 130 may be a multi-layer structure or in the form of spacers to provide better insulation and self-alignment effects.

Please refer to FIGS. 5A and 5B. After the cell insulating liner 130 and the filling insulating layer 132 are formed, the isolation line mask pattern 134 is then formed on the flush plane of the semiconductor substrate 100. In one embodiment, the isolation line mask pattern 134 on storage region 100A may extend in parallel to each other in the first direction D1, thereby crossing the bit line patterns BL, Ble. Similar to the cell line mask pattern 128 in FIGS. 2A and 2B, the cell line mask pattern 128 can be formed by double patterning technology, so that its width can be smaller than the limit of the photolithography tool. Unlike the cell line mask pattern 128, the isolation line mask pattern 134 is a sacrificial pattern after removing the self-aligned spacers in the double patterning technology, and the removed self-aligned spacer pattern forms an isolation line pattern 136 as shown in the figure, which extends in first direction to peripheral region 100B and overlaps with the peripheral gate pattern 118p thereon. More specifically, as shown in FIG. 5A, the isolation line mask pattern 134 on storage region 100A extends in the first direction D1, which alternately extends through the middle contact plug 114 on the different cell active part CA and the two end positions of the second source/drain region SD2 (i.e., the storage node), and may partially overlaps with the cell gate electrode GE. The isolation line pattern 136 on the storage region 100A also extends in the first direction D1, which extends through the contact plug 114 in the middle on different cell active part CA and the position between the second end source/drain regions SD2 at the end. In one embodiment, both isolation line mask pattern 134 and isolation line pattern 136 may extend to peripheral region 100B and overlap with peripheral gate pattern 118p thereon, wherein adjacent isolation line patterns 136 in pairs may be further provided with connecting end 136a on the peripheral region 100B. In one embodiment, the isolation line pattern 136 may expose part of the capping layer 126 and the filling insulating layer 132 on the storage region 100A, and the exposed region of the filling insulating layer 132 may define the storage node contact isolation structure to be formed subsequently. The isolation line mask pattern 134 may be formed by insulating material with etch selectivity with respect to the filling insulating layer 132, such as silicon nitride and/or silicon oxynitride. In other embodiment, the isolated line mask pattern 134 may be directly formed by photoresist.

Please refer to FIGS. 6A and 6B. After the isolated line mask pattern 134 and the isolation line pattern 136 are formed, the isolation line mask pattern 134 is then used as a mask for photolithography process to remove the insulating layer 132 exposed on the storage region 100A, so that the contact isolation structure groove 138 located between the bit line patterns BL, BLe is formed. The cell region covered by isolation line mask pattern 134, such as the region intercepted by the section line Π-Π′, is not affected. In one embodiment, it should be noted that the exposed insulating layer 132 is only between the bit line patterns BL, BLe on the storage region 100A, so the contact isolation structure groove 138 may only be formed between the bit line patterns BL, BLe on the storage region 100A, and the contact isolation structure groove 138 may expose the underlying insulating liner 130, which serves as an etching stop layer. The exposed surface of other storage region 100A and peripheral region 100B is the capping layer 126, and this photolithography process may also remove the exposed capping layer 126 with certain thickness, so that parts of the isolated line pattern 136 is transferred to the capping layer 126 to form isolation line groove 140. The isolation line groove 140 may extend through the peripheral region 100B in the first direction D1 and extend through the peripheral gate pattern 118p. The isolation line mask pattern 134 may be removed after the aforementioned photolithography process.

Please refer to FIGS. 7A and 7B. After the contact isolation structure groove 138 and the isolation line groove 140 are formed, the insulating material is then filled into the contact isolation structure groove 138 and the isolation line groove 140, so that the contact isolation structure 142 (may also be referred as storage cell isolation structure) is formed. In one embodiment, the contact isolation structure 142 may comprise the lower half 142a on contact isolation structure groove 138 and the upper half 142b on isolation line groove 140, wherein the contact isolation structure 142 outside the storage region 100A only has the upper half 142b extending in first direction D1 to peripheral region 100B, locating in the capping layer 126 and overlapping with peripheral gate pattern 118p, and adjacent upper halves 142b in pairs may also be provided with connecting end 142c on the peripheral region 100B. The lower half 142a of the contact isolation structure 142 is located in the previously formed contact isolation structure groove 138 and arranged in an array. It can be seen that more than one upper half 142b of the contact isolation structure 142 may overlap with a peripheral gate pattern 118p. The planarized contact isolation structure 142 and the capping layer 126 are flush. After the contact isolation structure 142 is formed, an etching process is then performed to remove the remaining insulating layer 132 on the storage region 100A, so that the storage node contact recess 144 is formed on storage region 100A. The etching process removes both cell insulating liner 130 and insulating layer 110 on bottom surface, so that the second source/drain region SD2 (i.e., location of storage nodes) of the underlying cell active part CA and the device isolation pattern 102 are exposed. Other exposed surface is the region of capping layer, including peripheral region 100B, which is not affected. In one embodiment, the contact isolation structure 142 may be formed of an insulating material with etching selectivity with respect to the filling insulating layer 132, such as silicon nitride and/or silicon oxynitride, and the upper half 142b and the lower half 142a thereof are composed of the same material layer.

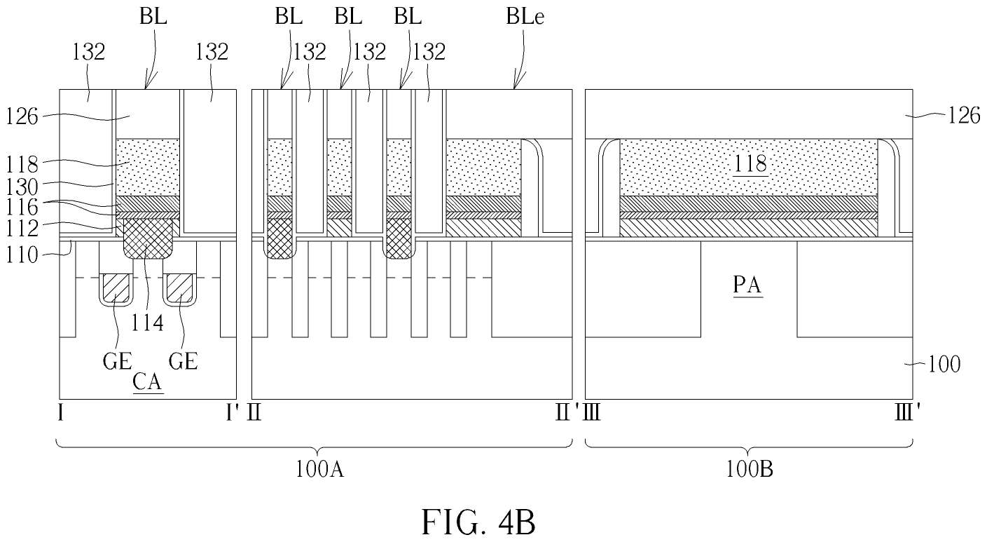

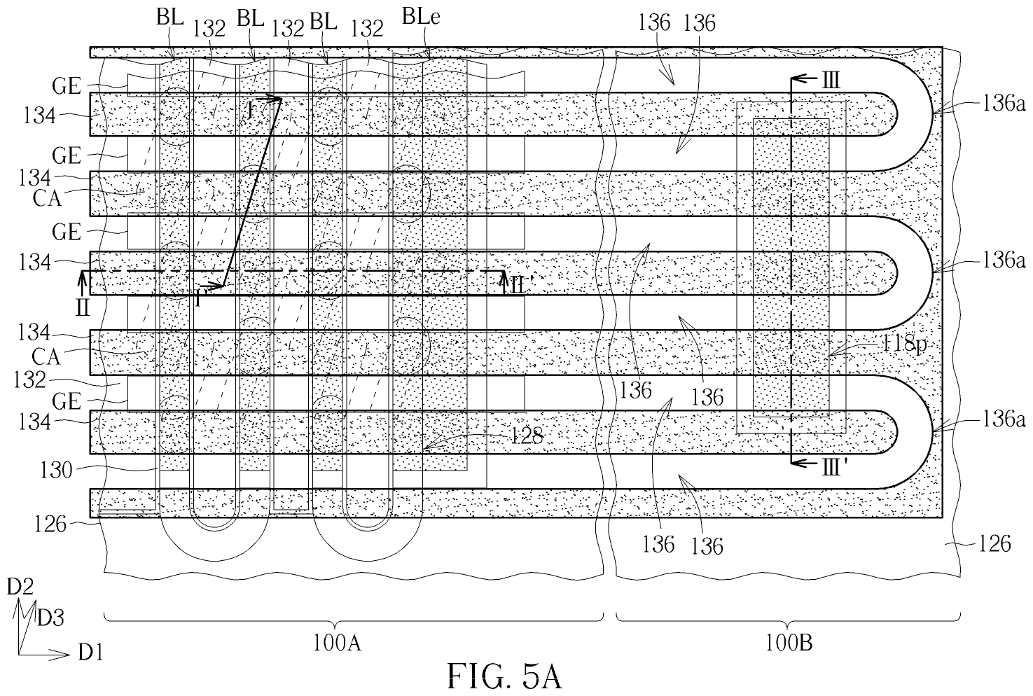

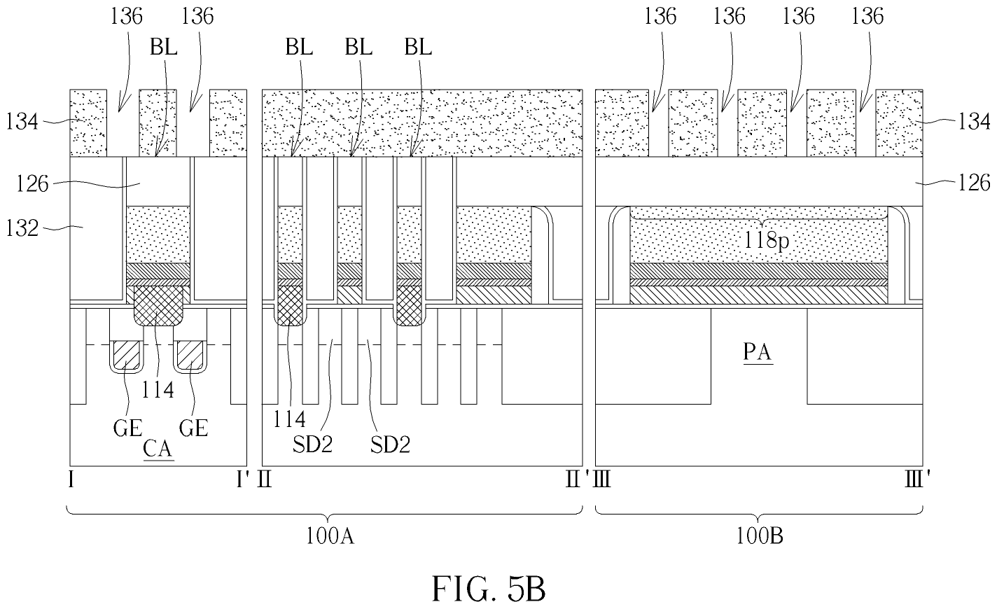

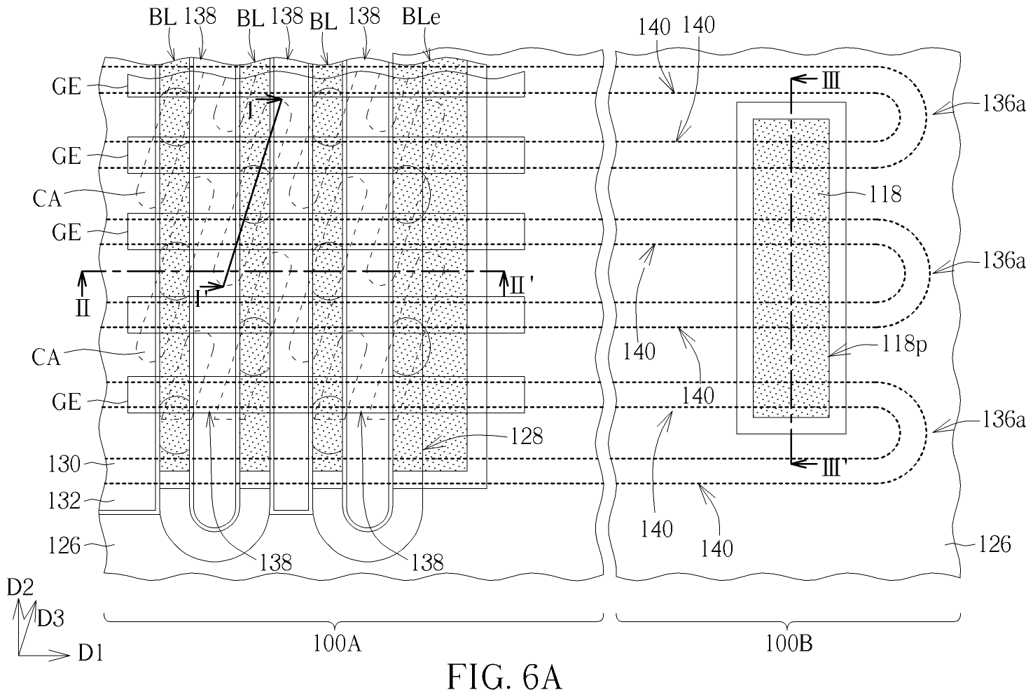

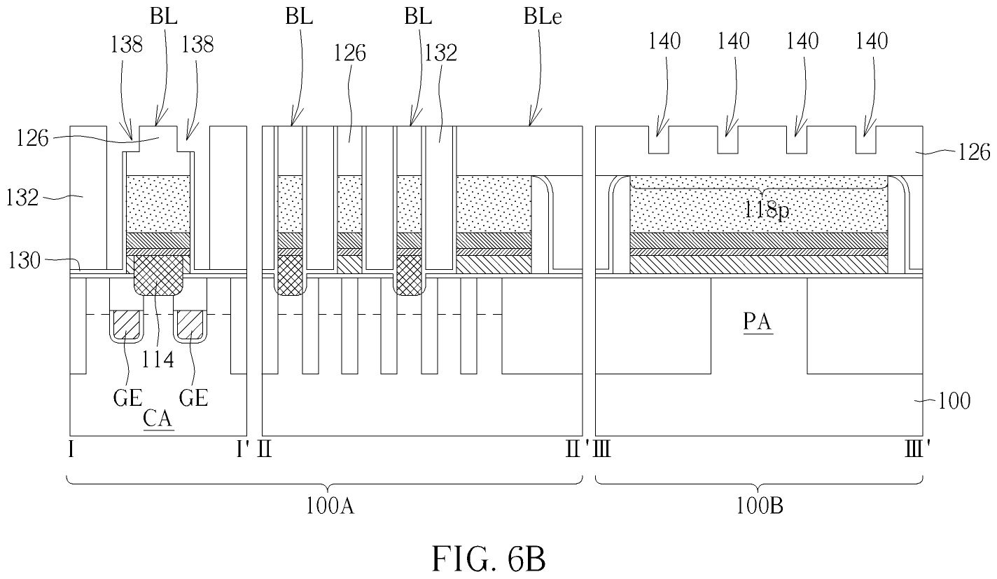

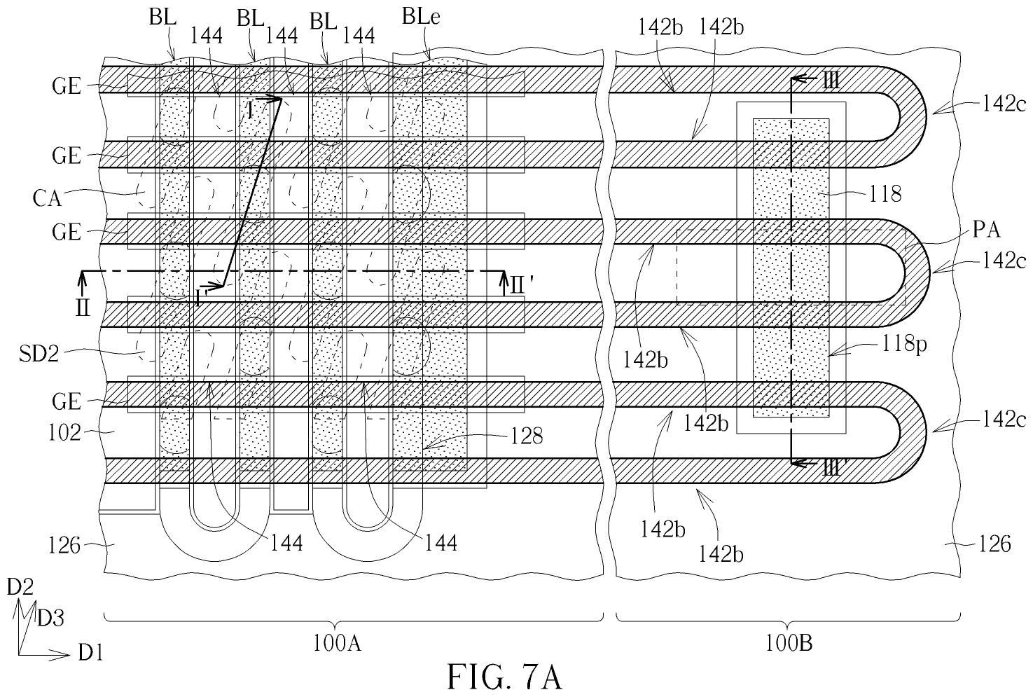

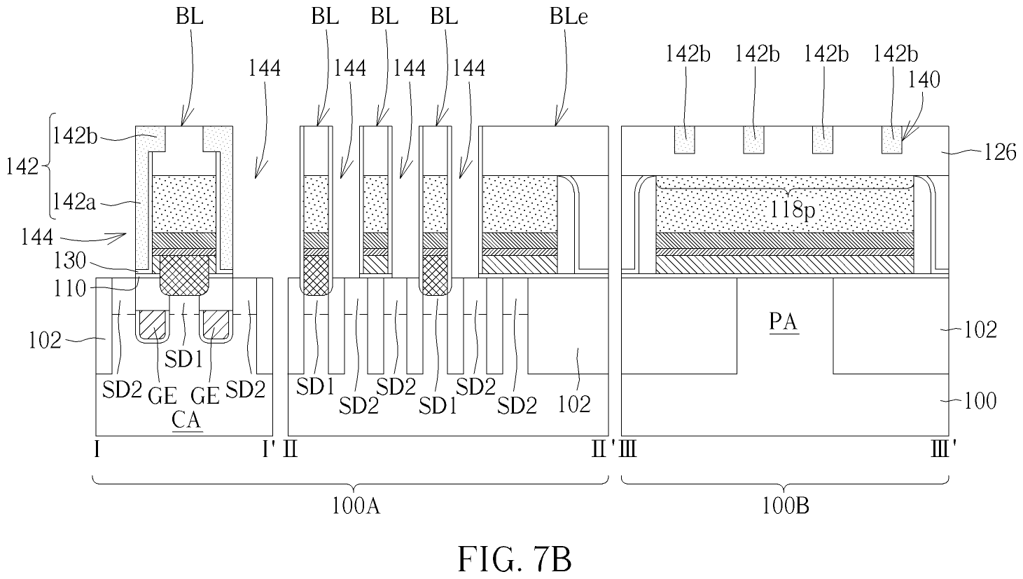

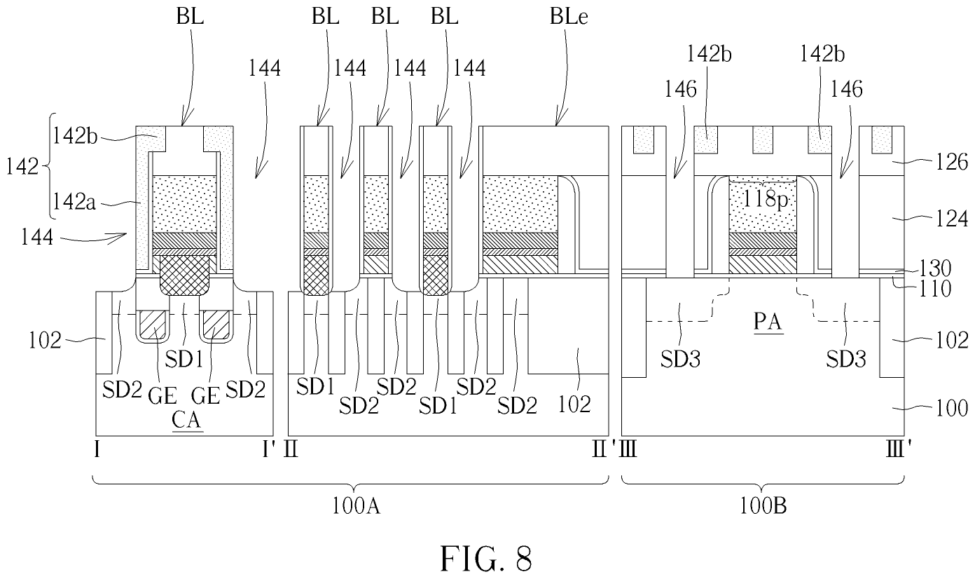

The following embodiments describe the steps of forming storage node contacts in the semiconductor process of the present invention with reference to FIGS. 8-11. It is noted that in the figures of the embodiment, the orientation of peripheral gate pattern 118p on peripheral region 100B is different from previous embodiments, and cross-section thereof sections through the source/drain region SD3 of the peripheral device to clearly express the influence of this process step on the peripheral region.

Please refer to FIG. 8. After the insulating layer 132 is removed, a photolithography process is then performed in the peripheral region 100B to form the contact hole 146. In one embodiment, the contact hole 146 sequentially extends through the stacked structure of capping layer 126, interlayer dielectric 124, cell insulating liner 130, and insulating layer 110 on the peripheral region 100B to contact the underlying third source/drain region SD3. In addition, parts of the aforementioned upper half 142b of the contact isolation structure 142 may be penetrated by the contact hole 146. Furthermore, in one embodiment, this photolithography process may further etch the second source/drain region SD2 and the device isolation pattern 102 exposed from the storage node contact recess 144 on the storage region 100A, so that the storage node contact recess 144 is recessed to facilitate the formation of the embedded contact of the storage node, but is not limited thereto.

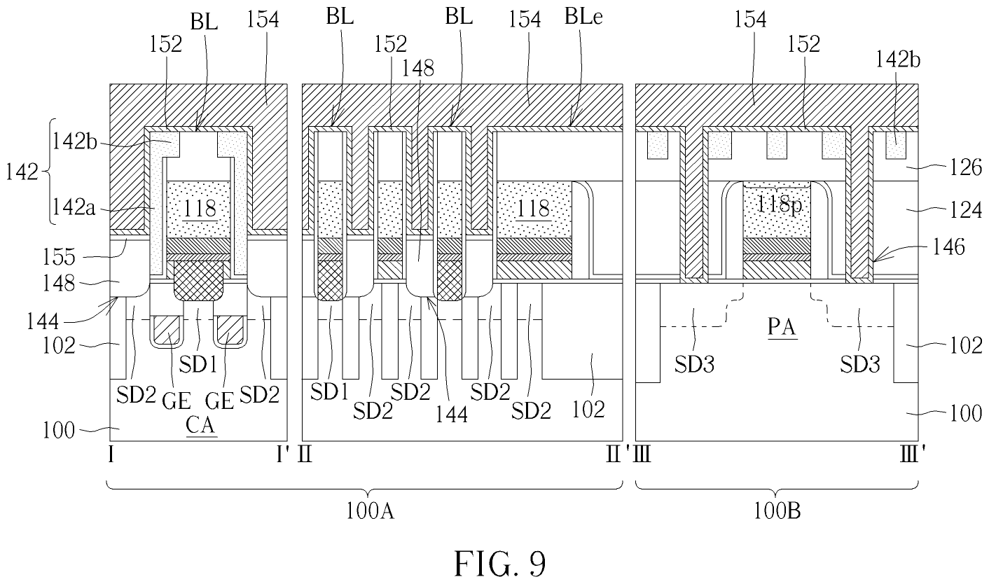

Please refer to FIG. 9. After the contact hole 146 is formed, the embedded contact 148 of storage node is then formed on storage node contact recess 144 of the storage region 100A. The embedded contact 148 may contact the corresponding second source/drain SD2 on storage region 100A, and in the present embodiment, the embedded contact 148 is not formed on peripheral region 100B, which may be achieved by forming mask on the peripheral region 100B. The height of embedded contact 148 is preferably lower than the top surface of the hard mask layer 118, and its material may comprise epitaxial silicon, polysilicon or amorphous silicon, etc. In other embodiments, the embedded contact 148 may not be formed, but not limited thereto. Then, the barrier layer 152 and the conductive layer 154 are formed in storage node contact recess 144 of the storage region 100A and in contact hole 146 of peripheral region 100B, wherein the barrier layer 152 may be conformally formed on the structural topography of the semiconductor substrate 100, and the conductive layer 154 fills up the remaining storage node contact recess 144 and the contact hole 146 and covers the entire semiconductor substrate surface. In one embodiment, the barrier layer 152 on the storage region 100A may contact the embedded contact 148, and the barrier layer 152 on the peripheral region 100B directly contacts the third source/drain region SD3 in the peripheral active part PA. The material of the barrier layer 152 may comprise titanium (Ti), titanium nitride (TiN), tantalum (Ta), tantalum nitride (TaN) or a combination thereof, and the material of the conductive layer 154 may comprise tungsten (W), tungsten nitride (WN), titanium (Ti), nickel (Ni), cobalt (Co), aluminum (Al) or combinations thereof. A metal silicide layer 156 may be further formed between the barrier layer 152 and the embedded contact 148 to provide better contact effects.

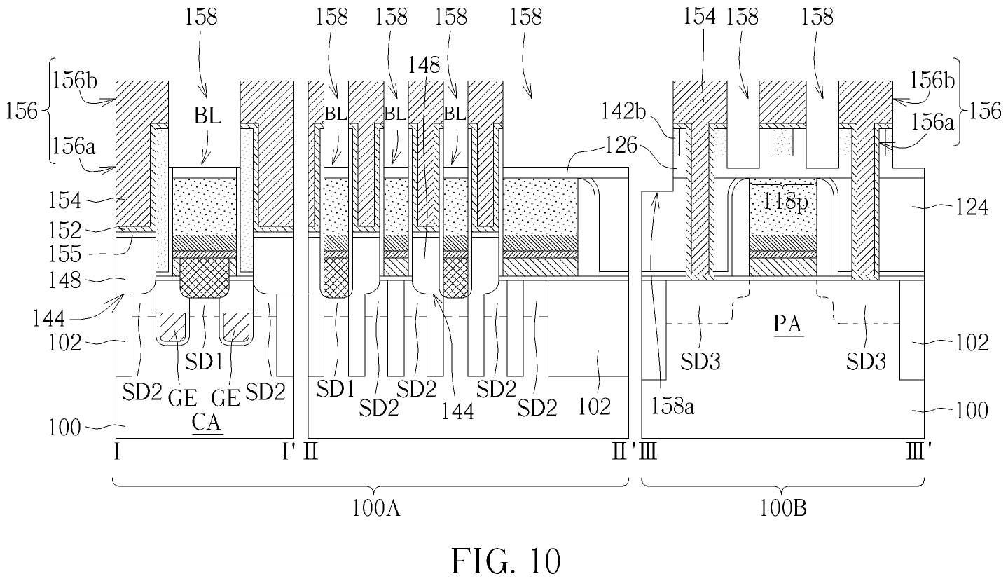

Please refer to FIG. 10. After the barrier layer 152 and the conductive layer 154 are formed, a photolithography process is then performed to pattern the barrier layer 152 and the conductive layer 154 outside the storage node contact recess 144 and the contact hole 146, so that the storage node contact 156 is formed. In one embodiment, the storage node contact 156 can be divided into a lower contact plug portion 156a and an upper contact pad portion 156b, wherein the contact plug portion 156a is located in the aforementioned storage node contact recess 144, and the contact pad portion 156b is located in the upper half 142b of the contact isolation structure 142 and above the height of the top surface of the capping layer 126. In one embodiment, a contact pad isolation groove 158 is formed between the patterned contact pad portions 156b, which may extend through the capping layer 126 with certain thickness into the capping layer 126, for example, its bottom surface is lower than the height of the upper half 142b of the contact isolation structure 142 or extends through the entire capping layer 126 deeply into the interlayer dielectric 124 (that is, lower than the height of the bottom surface of the capping layer 126, as shown by the groove 158a). The sidewall of the contact pad isolation recess 158 may comprise conductive layer 154, barrier layer 152, the upper half 142b of the contact isolation structure 142 and/or interlayer dielectric 124, and the barrier layer 152 is not on surface of the contact pad isolation recess 158. In one embodiment, the contact pad isolation recess 158 generally overlaps the bit line pattern BL in vertical direction. However, in other embodiments, the contact pad position 156b of the storage node contact 156 may be horizontally offset relative to the contact plug position 156a, so that the contact pad isolation recess 158 and the contact pad portion 156b are partially overlapped with the underlying bit line pattern BL. In general, the storage node contact 156 and the storage cell formed thereon later are arranged in an array on the substrate surface. It should be noted that in the present invention, the aforementioned patterning process used to form the storage node contact 156 on the storage region 100A may also be used to form the same recess and contact pad structure (the peripheral region may comprise peripheral circuit patterns) on the peripheral region 100B, and similar to the contact hole 146 of FIG. 8, these recesses 158 may extend through some of the upper halves 142b of the contact isolation structures 142.

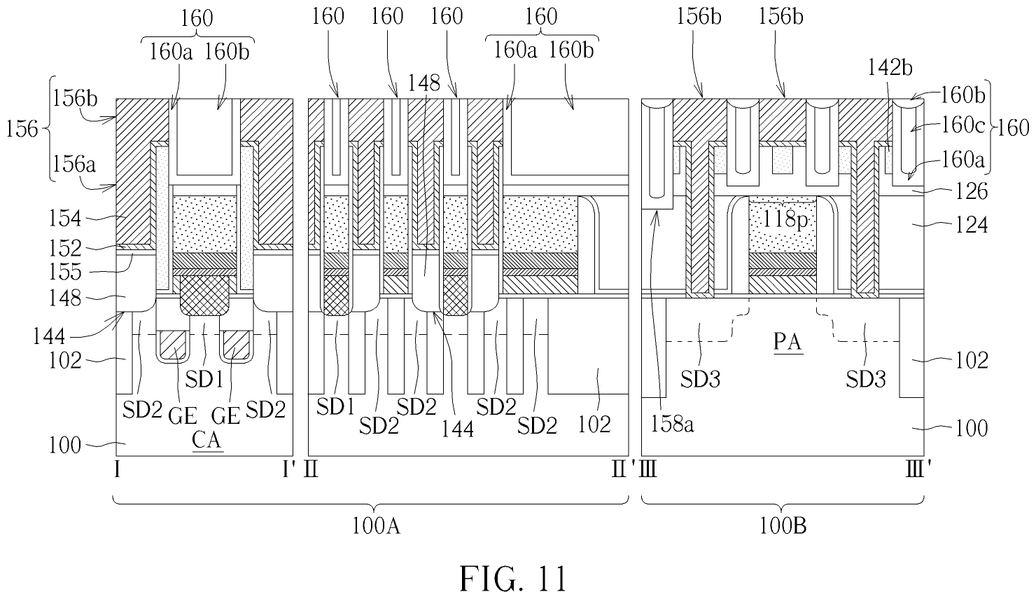

Please refer to FIG. 11. After the storage node contact 156 and contact pad isolation recess 158 are formed, the contact pad isolation structure 160 is then formed in the contact pad isolation recess 158. In one embodiment, the contact pad isolation structure 160 may comprise a first insulating layer 160a on the bottom and sidewall of the contact pad isolation structure 160 and a second insulating layer 160b on the top of the contact pad isolation structure 160 and covering the first insulating layer 160a. In one embodiment, the first insulating layer 160a may be conformally formed on the structural topography of the semiconductor substrate, and the second insulating layer 160b may fill the remaining contact pad isolation groove 158. In addition, in the case where the width of the contact pad isolation recess 158 is smaller, the second insulating layer 160b may not fill the remaining the contact pad isolation recess 158, instead, it can define the air gap 160c in the contact pad isolation structure 160 together with the first insulating layer 160a, but not limited thereto. In one embodiment, the air gap 160c may further improve the isolation effect of contact pad isolation structure 160. The top surface of planarized contact pad isolation structure 160 and the top surface of storage node contact 156 are preferably flush. In addition, the contact pad isolation structure 160 may extend into the capping layer 126, for example, with its bottom surface lower than the height of the upper half 142b of the contact isolation structure 142 or extends through entire capping layer 126 deeply into the interlayer dielectric 124 (that is, lower than the height of the bottom surface of the capping layer 126, as shown by the recess 158a). The contact pad isolation structure 160 may contacts with contact isolation structure 142, and the bottom surface thereof is lower than the bottom surface of contact isolation structure 142. In general, in one embodiment, the contact pad isolation structure 160 is arranged in an array on the substrate surface. The material of first insulating layer 160a may be silicon nitride, and the material of the second isolation layer 160b may be silicon carbonitride (SiCN).

Please refer to FIG. 12, which is a schematic cross-section of a semiconductor device according to another embodiment of the present invention. The embodiment takes two adjacent peripheral gate patterns 118p as an example, the contact 156 extends from the position between the two peripheral gate patterns 118p through the layer structure like the capping layer 126 and interlayer dielectric 124 to connect the third source/drain region SD3 in the semiconductor substrate 100, and the interlayer dielectric 124 may cover the top surface and sidewall of the peripheral gate pattern 118p, but not limited thereto. The contact 156 may be further connected to the interconnects above through a via 164. In the embodiment of FIG. 12, the contact pad isolation structure 160 may comprise a first insulating layer 162a on the bottom and sidewall of the contact pad isolation structure 162 and a second insulating layer 162b conformally formed on the capping layer 126, the first insulating layer 162a, and the surface of contact pad part 156b. The bottom of the second insulating layer 162 may be lower than the first insulating layer 162a, contact pad position 156b, and the bottom of the upper half 142b of the contact isolation structure 142. In addition, as aforementioned, in the case where the width of contact pad isolation recess is larger, the insulating layer may fill the remaining contact pad isolation groove space without forming air gap. As a result, the contact pad isolation structure 162 may further comprise a third insulating layer 162c, which is located on the second insulating layer 162b and fills the remaining recess space. In one embodiment, the bottom surface of the third insulating layer 162c of the contact pad isolation structure 162 may be lower than the bottom of the first insulating layer 162a (as 162c-1), higher than the bottom of the first insulating layer 162a (as 162c-2), or flush with the bottom of the first insulating layer 162a. In one embodiment, the material of the first insulating layer 162a and the third insulating layer 162c may be silicon nitride, and the material of the second insulating layer 160b may be silicon carbon nitride (SiCN).

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a substrate, comprising a first region and a second region;
a gate structure, disposed on said substrate of said second region;
a sidewall structure, disposed on two sides and top surface of said gate structure;
a first dielectric layer, disposed on said sidewall structure;
a second dielectric layer, disposed on said first dielectric layer;
a first insulating structure, disposed in said second dielectric layer; and
a second insulating structure, penetrating through said first insulating structure.

2. The semiconductor structure of claim 1, further comprising:
a first contact structure, comprising a lower portion of a contact plug and an upper portion of a conductive pad, wherein said contact plug penetrating through said first dielectric layer and said second dielectric layer and said conductive pad disposed on said second dielectric layer and said first insulating structure, wherein said second insulating layer penetrates through said conductive pad.

3. The semiconductor structure of claim 1, wherein a bottom surface of said second insulating structure is lower than a bottom surface of said first insulating structure.

4. The semiconductor structure of claim 1, wherein a bottom surface of said second insulating structure is in said first dielectric layer.

5. The semiconductor structure of claim 1, wherein a top surface of said first insulating structure aligns with a top surface of said second dielectric layer.

6. The semiconductor structure of claim 1, wherein said second insulating structure comprises a first insulating layer and a second insulating layer disposed on said first insulating layer, wherein said first insulating layer contacts said second dielectric layer, a sidewall of said conductive pad, and a sidewall of said first insulating structure, said second insulating layer contacts a sidewall of said first insulating layer.

7. The semiconductor structure of claim 6, wherein said first insulating layer and said second insulating layer defines an air gap in said second insulating structure.

8. The semiconductor structure of claim 6, wherein said second insulating structure further comprises a third insulating layer disposed on said second insulating layer, wherein said second insulating layer contacts a top surface of said conductive pad.

9. The semiconductor structure of claim 8, wherein a bottom surface of said second insulating layer is lower than a bottom surface of said first insulating layer, a bottom surface of said conductive pad and a bottom surface of said first insulating structure.

10. The semiconductor structure of claim 8, wherein a bottom of said third insulating layer is lower than a bottom of said first insulating layer.

11. The semiconductor structure of claim 8, wherein a bottom of said third insulating layer aligns with a bottom of said first insulating layer.

12. The semiconductor structure of claim 8, wherein a bottom of said third insulating layer is higher than a bottom of said first insulating layer.

13. The semiconductor structure of claim 1, further comprising:
multiple bit lines disposed on said first region and extending in a first direction;
multiple second contact structures disposed on said first region and between said bit lines, and said second contact structures are arranged in an array; and
multiple contact isolation structures disposed on said first region, between said bit lines and between said second contact structures, and said contact isolation structures are arranged in an array, and said storage cell isolation structure is formed of the same material layers as said first insulating structure.

14. The semiconductor structure of claim 13, wherein said first insulating structure extends in a second direction, and said second direction is orthogonal to said first direction.

15. The semiconductor structure of claim 13, wherein contact pads are formed on second contact structures, and said contact pads are separated by contact pad isolation structures, said contact pad isolation structures are formed of the same material layers as said second insulating structure, and a top surface of the contact pads, a top surface of said contact pad isolation structures, a top surface of said second insulating structure, and a top surface of said conductive pad are substantially flush.

16. The semiconductor structure of claim 14, wherein at least two adjacent said first insulation structures have an interconnected end in said first direction.

17. A method of manufacturing semiconductor structure, comprising:
providing a substrate comprising a first region and a second region;
forming a gate structure on said substrate of said second region;
forming a sidewall structure on two sides and top surface of said gate structure;
forming a first dielectric layer on said sidewall structure;
forming a second dielectric layer on said first dielectric layer;
forming a first insulating structure in said second dielectric layer; and
forming a second insulating structure penetrating through said first insulating structure.

18. The method of manufacturing semiconductor structure of claim 17, further comprising:
forming a first contact structure, said first contact structure comprises a lower portion of a contact plug and an upper portion of a conductive pad, wherein said contact plug penetrating through said first dielectric layer and said second dielectric layer and said conductive pad disposed on said second dielectric layer and said first insulating structure, wherein said second insulating layer penetrates through said conductive pad.

19. The method of manufacturing semiconductor structure of claim 17, wherein said forming a first insulating structure in said second dielectric layer further comprises:
simultaneously forming contact isolation structures on said first region.

20. The method of manufacturing semiconductor structure of claim 17, wherein step of forming said second insulating structure simultaneously forms a contact pad isolation structure on said storage region.
